(19) United States
(12) Patent Application Publication
(10) Pub. No.: US 2007/0145467 A1
(43) Pub. Date: Jun. 28, 2007

(54) EEPROMs with Trenched Active Region Structures and Methods of Fabricating and Operating Same

(75) Inventors: Geun-sook Park, Gyeonggi-do (KR); Byung-sun Kim, Gyeonggi-do (KR); Sang-bae Yi, Seoul (KR); Ho-ik Hwang, Seoul (KR); Myung-hee Kim, Gyeonggi-do (KR); Hye-young Park, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/538,239

(22) Filed: Oct. 3, 2006

(30) Foreign Application Priority Data
Dec. 23, 2005 (KR) 2005-0128746

(51) Int. Cl. H01L 29/788

(52) U.S. Cl. 257/315

(57) ABSTRACT

An EEPROM includes a semiconductor substrate and a device isolation region defining first, second and third active regions in the semiconductor substrate. The EEPROM also includes at least one first insulation region in at least one first trench in the first active region. A floating gate insulation layer is disposed on the at least one first insulation region and the first, second and third active regions and a floating gate conduction layer is disposed on the floating gate insulation layer. Impurity-containing regions may be disposed in each of the first, second and third active regions at respective sides of the floating gate conduction layer. The floating gate insulation layer may include at least one thinned portion proximate the at least one first insulation region, which may aid Fowler-Nordheim tunneling at this site.

### CROSS-REFERENCE TO RELATED APPLICATION

This application claims the benefit of Korean Patent Application No. 10-2005-0128746, filed on Dec. 23, 2005, in the Korean Intellectual Property Office, the disclosure of which is incorporated herein in its entirety by reference.

### BACKGROUND OF THE INVENTION

The present invention relates to semiconductor devices, and more particularly, to electrically erasable programmable read-only memory (EEPROM) nonvolatile semiconductor devices.

Memories are semiconductor integrated circuits (ICs), which can store data. Memories may be generally classified into read only memory (ROM) and random access memory (RAM) based on data volatility, i.e., RAM typically can be written to and read from and is usually volatile. ROM typically can be read from, but not written to, and typically is nonvolatile and holds its data even when the power is turned off. Therefore, ROM is widely used when the same task needs to be repeatedly performed or when a program does not need to be modified.

An electrically erasable programmable ROM (EEPROM) is a type of ROM that can be programmed and erased electrically. A typical EEPROM includes a tunnel insulation layer formed in an active region of a semiconductor substrate, a gate insulation layer surrounding the tunnel insulation layer, and a memory transistor formed by stacking a floating gate and a control gate. A typical EEPROM further includes source/drain regions formed in the semiconductor substrate on respective sides of the gates. The EEPROM typically writes and erases data by applying a voltage to the control gate so that electrons can Fowler-Nordheim (F-N) tunnel through the tunnel insulation layer.

Recently, system-on-chip (SoC) devices incorporating a logic device and a memory device into one chip have been developed. An SoC that integrates functions into one chip may be advantageous in view of cost and size, compared to separately manufacturing respective semiconductor chips for performing respective functions,

An SoC may include logic and an EEPROM. In such a device, the logic and the EEPROM typically are manufactured using a common process. The logic may include a transistor with a single-gate structure, while the EEPROM may include a transistor with a stacked-gate structure as described above. Therefore, a manufacturing process for producing an SoC including logic and an EEPROM may be very complicated.

To address this problem, EEPROMs with a single-gate structure have been developed. An EEPROM with a single-gate structure may include a programming MOS transistor for performing data programming and reading operations and a control MOS transistor for controlling the EEPROM. Transistors of a conventional EEPROM with a single-gate structure may share a common floating gate.

An EEPROM with a single-gate structure may allow capacitive coupling between a control well and a gate to be generated in the control MOS transistor, thereby allowing F-N tunneling of electrons to occur in the programming MOS transistor. Therefore, it may be desirable to increase the degree of capacitive coupling between the control well and the floating gate in order to increase the programming speed of the EEPROM. This may entail increasing the area of the floating gate capacitively coupled to the control well. However, simply increasing the area of the floating gate may run contrary to the desire to reduce the size of the semiconductor device. Therefore, efforts are being made to increase the programming speed of EEPROMs without increasing EEPROM size.

### SUMMARY OF THE INVENTION

In some embodiments of the present invention, an integrated circuit device includes a semiconductor substrate, an isolation region defining an active region in the semiconductor substrate. At least one filling region is disposed in at least one trench in the active region. A floating gate insulation layer is disposed on the at least one filling region and the active region, and a floating gate conductive layer is disposed on the floating gate insulation layer. The floating gate insulation layer may include thinned portions proximate the at least one filling region. The at least one trench may have a linear shape and/or a quadrangular shape. The active region may have a linear shape and/or a quadrangular shape.

Further embodiments of the present invention provide an electrically erasable programmable read-only memory (EEPROM). The EEPROM includes a semiconductor substrate and a device isolation region defining first, second and third active regions in the semiconductor substrate. The EEPROM also includes at least one first insulation region in at least one first trench in the first active region. A floating gate insulation layer is disposed on the at least one first insulation region and the first, second and third active regions and a floating gate conduction layer is disposed on the floating gate insulation layer. The EEPROM may further include impurity-containing regions in each of the first, second and third active regions at respective sides of the floating gate conduction layer. The floating gate insulation layer may include at least one thinned portion proximate the at least one first insulation region. The first trench may have a linear shape and/or a quadrangular shape. The first active region may have a linear shape and/or a quadrangular shape.

In further embodiments, the EEPROM further includes at least one second insulation region in at least one second trench formed in the second active region, and the floating gate insulation layer is disposed on the at least one second insulation region. The floating gate insulation layer may include at least one thinned portion proximate the at least one second insulation region.

In further embodiments of the present invention, the EEPROM includes an erase well in the semiconductor substrate in the first active region and including impurities of a first conductivity type, a read well in the semiconductor substrate in the second active region and including impurities of a second conductivity type opposite to the first conductivity type and a control well in the semiconductor substrate in the third active region and including impurities of the first conductivity type. A first line may be connected to the erase well and the impurity-containing regions in the first active region, a second line may be connected to the read well and one of the impurity implanted regions in the second active region, a third line may be connected to the other one of the impurity implanted regions in the second active region and a fourth line may be connected to the control well and impurity implanted regions in the third active region. The EEPROM may further include a deep well including impurities of the first conductivity type and surrounding the read well.

Additional embodiments of the present invention provide methods of fabricating an EEPROM. A plurality of device isolation layers defining first, second and third active regions in a semiconductor substrate are formed. At least one trench is formed in the first active region. At least one first insulation region is formed in the at least one trench. A floating gate insulation layer is formed on the first, second and third active regions and on the at least one first insulation region. A floating gate conduction layer is formed on the floating gate insulation layer. The at least one trench region may be formed by forming an etching mask on the semiconductor substrate including at least one opening exposing at least one portion of the first active region and etching the substrate using the etching mask to form the at least one trench. The floating gate insulation layer may include at least one thinned portion proximate the at least one first insulation region.

Impurities may be implanted into the first, second and third active regions using the floating gate conduction layer as an ion implantation mask, thereby forming impurity-implanted regions. In some embodiments, impurities of a first conductivity type may be implanted in the first active region to form an erase well, impurities of a second conductivity type opposite to the first conductivity type may be implanted in the second active region to form a read well. Impurities of the first conductivity type may be implanted in the third active region to form a control well. Impurities of the first conductivity type may be implanted to form a deep well surrounding the read well.

A first line connected to the erase well and the impurity implanted regions of the first active region may be formed. A second line connected to the read well and one of the impurity implanted regions of the second active region may be formed. A third line connected to the other one of the impurity implanted regions of the second active region may be formed. A fourth line connected to the control well and the impurity implanted regions of the third active region may be formed.

Further embodiments of the present invention provide methods of operating an EEPROM comprising first, second and third active regions defined on a semiconductor substrate by device isolation layers, at least one insulation region in at least one trench in the first active region, a floating gate insulation layer on the at least one insulation region and the first, second and third active regions, a floating gate conduction layer on the floating gate insulation layer, and impurity-containing regions in the first, second and third active regions at respective sides of the floating gate conduction layer. Data is programmed by respectively applying a ground voltage and a program voltage to the first active region and the third active region. The programmed data is read by respectively applying a read voltage and a source voltage to the third active region and one of the impurity-containing regions of the second active region. The programmed data is erased by respectively applying the ground voltage and an erase voltage to the third active region and the first active region. Electrons may be F-N tunneled through the floating gate insulation layer formed on the semiconductor substrate of the first active region contacting the filling region, into the floating gate conduction layer, during the programming of data. Electrons may be F-N tunneled from the floating gate conduction layer, through the floating gate insulation layer formed on the semiconductor substrate of the first active region contacting the filling region, into the semiconductor substrate, during the erasing of the programmed data.

The EEPROM may further include an erase well in the first active region and including impurities of a first conductivity type, a read well in the second active region and including impurities of a second conductivity type opposite to the first conductivity type and a control well in the semiconductor substrate of the third active region and including impurities of the first conductivity type. Programming of data may include applying the ground voltage to the erase well and the impurity-containing regions of the first active region, applying the ground voltage to the read well and the impurity-containing regions of the second active region and applying the program voltage to the control well and the impurity-containing regions of the third active region. Reading of the programmed data may include applying the ground voltage to the erase well and the impurity-containing regions of the first active region, applying the ground voltage to the read well and one of the impurity-containing regions of the second active region, applying the source voltage to another one of the impurity-containing regions of the second active region and applying the read voltage to the control well and the impurity-containing regions of the third active region. Erasing of the programmed data may include applying the erase voltage to the erase well and the impurity-containing regions of the first active region, applying the ground voltage to the read well and the impurity-containing regions of the second active region, and applying the ground voltage to the control well and the impurity-containing regions of the third active region.

### BRIEF DESCRIPTION OF THE DRAWINGS

The above and other features and advantages of the present invention will become more apparent by describing in detail exemplary embodiments thereof with reference to the attached drawings in which:

FIG. 1 is an equivalent circuit diagram of a unit cell of an EEPROM according to some embodiments of the present invention;

FIG. 2 is a layout diagram of an EEPROM unit cell as illustrated in FIG. 1 according to some embodiments of the present invention;

FIGS. 3A through 3C are layout diagrams illustrating first active regions of EEPROMs according to some embodiments of the present invention;

FIG. 4 is a perspective view of a section taken along a line IV-IV′ of FIG. 2;

FIG. 5 is a sectional view illustrating operations for programming data into an EEPROM according to some embodiments of the present invention;

FIG. 6 is a sectional view illustrating operations for reading data from an EEPROM according to some embodiments of the present invention; and

FIG. 7 is a sectional view illustrating operations for erasing data from an EEPROM according to some embodiments of the present invention.

### DETAILED DESCRIPTION OF EMBODIMENTS OF THE INVENTION

The present invention will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments and is not intended to be limiting of the invention. As used herein, the singular forms “a”, “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Embodiments of the present invention are described herein with reference to perspective illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will also be appreciated by those of skill in the art that references to a structure or feature that is disposed “adjacent” another feature may have portions that overlap or underlie the adjacent feature.

EEPROMs according to some embodiments of the present invention may be any EEPROM using F-N tunneling, such as a memory transistor with a single gate structure or a memory transistor formed by stacking a control gate and a floating gate. The embodiments described below include an EEPROM with a single gate structure, which includes a read transistor, a control MOS capacitor, and an erase MOS capacitor.

Some embodiments of the present invention provide EEPROMs that may be capable of high programming speed.

Some embodiments of the present invention also provide EEPROMs with a single-gate structure that may be capable of high programming speed without being made larger.

Some embodiments of the present invention also provide methods of fabricating an EEPROM with a single-gate structure that may increase programming speed without being made larger.

Some embodiments of the present invention also provide methods of efficiently operating an EEPROM with a single-gate structure that may increase programming speed without being made larger.

According to an aspect of the present invention, there is provided an EEPROM including an active region having at least one trench; and at least one filling region formed of an insulating material to fill the trench.

The active region having the trench is defined on a semiconductor substrate by a device isolation layer. The trench may have various shapes, such as a linear shape or a quadrangular shape. The depth and number of trenches may vary. A plurality of such filled trenches may be formed in order to increase programming speed. The trench may be shallow for convenience of fabrication. Moats may be generated in an edge region of the filling region contacting the semiconductor substrate of the active region.

The EEPROM further includes a floating gate insulation layer formed on the semiconductor substrate with the filling region. The moats may cause the floating gate insulation layer on the semiconductor substrate of the active region to be thinned proximate the filling region. The filling region and the floating gate insulation layer may be formed of the same material or different materials. The filling region and the floating gate insulation layer may be formed of an insulating material. Electrons can be F-N tunneled through the thin areas of the floating gate insulation layer. Accordingly, the programming speed can be increased.

The EEPROM further includes a floating gate conduction layer formed on the floating gate insulation layer. The floating gate conduction layer may be formed of polysilicon doped with impurities.

When a data reading operation is performed simultaneously with a data programming or erasing operation in the active region including the trench, it is desirable to reduce or prevent a leakage current during the data reading operation while enhancing the programming speed. Therefore, the number and shape of the filling regions may be determined considering both the enhancement of the programming speed and the reduction or prevention of a leakage current.

According to another aspect of the present invention, there is provided an EEPROM of a single-gate structure including: an active region having at least one trench, a program/erase transistor formed in the active region; and at least one filling region formed of an insulating material to fill the trench.

The EEPROM of the single-gate structure includes: first, second and third active regions defined on a semiconductor substrate by device isolation layers; at least one first filling region formed of an insulating material to fill at least one first trench formed in the first active region; a floating gate insulation layer formed on the first filling region and the first, second and third active regions; a floating gate conduction layer formed on the floating gate insulation layer; and impurity-implanted regions formed in active regions at both sides of the floating gate conduction layer.

The EEPROM of the single-gate structure may further include: an erase well formed in the semiconductor substrate of the first active region and including impurities of a first conductivity type; a read well formed in the semiconductor substrate of the second active region and including impurities of a second conductivity type opposite to the first conductivity type; and a control well formed in the semiconductor substrate of the third active region and including impurities of the first conductivity type. The EEPROM may further include a deep well including impurities of the first conductivity type and surrounding the read well. For example, an erase well and a control well including N-type impurities (e.g., As or P) may be formed on a P-type semiconductor substrate. The read well may be formed of P-type impurities with a different impurity concentration from that of the P-type semiconductor substrate.

The EEPROM of the single-gate structure may further include lines connected to the well or the impurity-implanted regions. For example, the EEPROM of the single-gate structure may further include; a first line connected commonly to the erase well and impurity implanted regions formed in the first active region; a second line connected commonly to the read well and one of impurity implanted regions formed in the second active region; a third line connected to the other one of the impurity implanted regions formed in the second active region; and a fourth line connected commonly to the control well and impurity implanted regions formed in the third active region.

Moats may be generated in the first filling region filling the first trench at a boundary surface contacting the semiconductor substrate of the active region. The moats may cause the floating gate insulation layer on the semiconductor substrate of the first active region to be thinned proximate the first filling region.

The EEPROM of the single-gate structure may further include a second filling region formed of an insulating material to fill at least one second trench formed in the second active region. The floating gate insulation layer formed on the semiconductor substrate of the second active region may be thinned proximate the second filling region. An electric field may be concentrated on the thinned region of the floating gate insulation layer, which may aid F-N tunneling of electrons. Accordingly, it is possible to increase the programming speed of the EEPROM without increasing the contact area between the floating gate and the control well.

The EEPROM of the single-gate structure includes a floating gate conduction layer formed on the active regions and the first filling region. The floating gate conduction layer may have various shapes, for example, a straight-line shape connecting an upper portion of the first filling region and upper portions of the active regions. When the EEPROM further includes a second filling region, the floating gate conduction layer may be further formed on the second filling region.

According to another aspect of the present invention, there is provided a method of fabricating an EEPROM. A plurality of device isolation layers defining first, second and third active regions are formed on a semiconductor substrate. The device isolation layer may be an STI layer. Thereafter, an etch mask for trench formation is formed on the semiconductor substrate of the first active region. The etch mask may have a high etch selectivity with respect to the semiconductor substrate, and may be a nitride layer.

The semiconductor substrate of the first active region is etched using the etch mask to form at least one trench. The shape of the opening of the etch mask may be determined depending on the shape of the trench. That is, when the trench is formed in plurality or in a linear or quadrangular shape, the opening of the etch mask may also be formed in plurality or in the linear or quadrangular shape.

The trench is filled with an insulating material to form at least one filling region. The filling region may be formed of an oxide material. As the semiconductor substrate may be damaged by the etching process for trench formation, the inner walls of the trench may be thermally oxidized to form a thermal oxide layer in order to cure the damage of the semiconductor substrate. Thereafter, an oxide layer may be deposited to fill the trench, thereby forming a filling region.

The etch mask is removed. When the etch mask is a nitride layer, it may be removed by wet etching. During the wet etching or the subsequent cleaning process, portions of the filling region contacting the semiconductor substrate of the first active region are removed to generate moats.

A floating gate insulation layer is formed on the semiconductor substrate from which the etch mask is removed. The floating gate insulation layer is formed on the filling region and the active regions. The floating gate insulation layer on the semiconductor substrate of the first active region may be thinned proximate the filling region. The floating gate insulation layer includes an oxide material. Therefore, when the filling region is also an oxide material, the boundary between the filling region and the floating gate insulation layer may become obscure. A floating gate conduction layer is formed on the floating gate insulation layer. The floating gate conduction layer may include polysilicon doped with impurities, for example, N-type impurities.

According to another aspect of the present invention, there is provided a method of operating an EEPROM. An EEPROM includes first, second and third active regions defined on a semiconductor substrate by a device isolation layer, at least one filling region formed of an insulating material to fill at least one trench formed in the first active region, a floating gate insulation layer formed on the filling region and the first, second and third active regions, a floating gate conduction layer formed on the floating gate insulation layer, and impurity-implanted regions formed in active regions at both sides of the floating gate conduction layer. Data is programmed by respectively applying a ground voltage and a program voltage to the first active region and the third active region. During the programming of data, electrons can easily be F-N tunneled through the floating gate insulation layer formed on the semiconductor substrate of the first active region contacting the filling region, into the floating gate conduction layer. The programmed data may be read by respectively applying a read voltage and a source voltage to the third active region and one of the impurity-implanted regions of the second active region. The programmed data may be erased by respectively applying the ground voltage and an erase voltage to the third active region and the first active region. During the erasing of the programmed data, electrons may be more easily F-N tunneled from the floating gate conduction layer, through the floating gate insulation layer formed on the semiconductor substrate of the first active region contacting the filling region, into the semiconductor substrate.

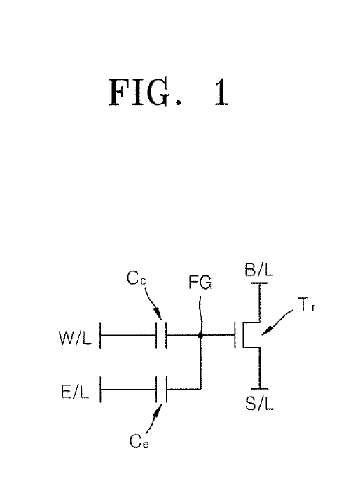

FIG. 1 is an equivalent circuit diagram of a unit cell of an EEPROM according to some embodiments of the present invention. Referring to FIG. 1, a control MOS transistor Cc is connected to a word line W/L and is used to control the operation of the EEPROM cell. An erase MOS capacitor Ce is connected to an erase line E/L and is used to erase or program (or write) data. A read transistor Tr has a source region connected to a source line S/L and a drain region connected to a bit line B/L and is used to read or program data. The control MOS capacitor Cc, the erase MOS transistor capacitor Ce, and the read transistor Tr are commonly connected to a floating gate FG. The control MOS capacitor Cc is capacitively coupled to the word line W/L and data is programmed, erased or read by the erase MOS capacitor Ce and the read transistor Tr.

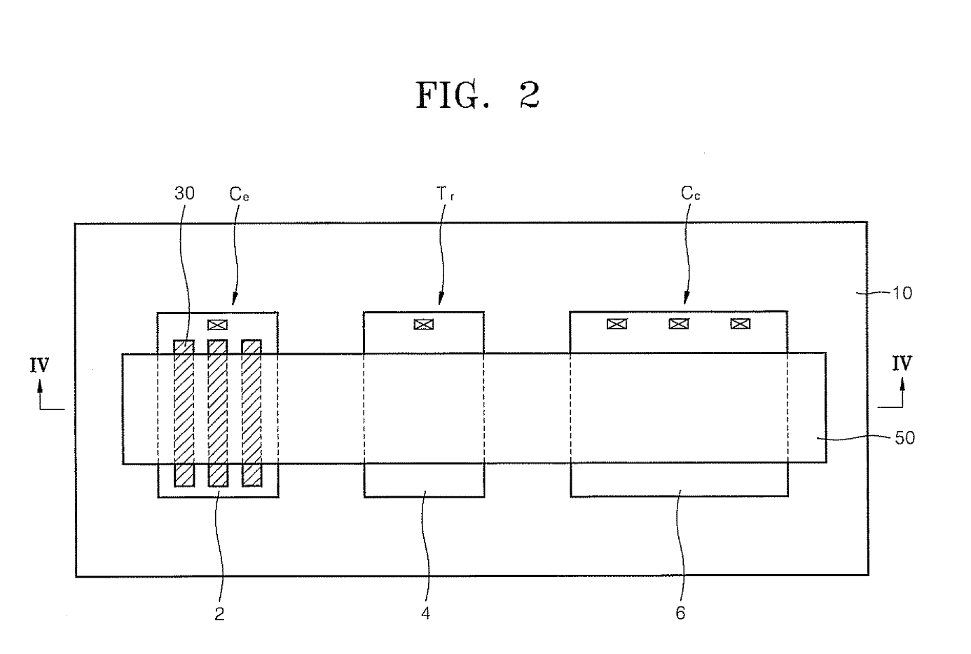

FIG. 2 is a layout diagram for the EEPROM unit cell illustrated in FIG. 1 according to some embodiments of the present invention. Referring to FIG. 2, a first active region 2, a second active region 4 and a third active region 6 are formed on a semiconductor substrate 10 and isolated from each other by a device isolation layer. An erase MOS transistor Ce, a read transistor Tr, and a control MOS transistor Cc may be respectively formed in the first active region 2, the second active region 4, and the third active region 6.

The active regions 2, 4 and 6 may be arranged in an order as desired for reliability or production ease. The first active region 2 includes a plurality of linear trenches. The EEPROM includes a plurality of filling (trench insulation) regions 30 formed by filling the trenches with an insulating material. Because the filling regions 30 are formed of an insulating material, they serve as device isolation layers in the first active region 2. Accordingly, the first active region 2 hereinafter represents the active region minus the filling region 30. A common floating gate insulation layer and a floating gate conductive layer 50 are formed on the filling regions 30 and the active regions 2, 4 and 6. The floating gate conductive layer 50 may be formed on at least portions of the filling regions 30. The floating gate conductive layer 50 may have various shapes depending on the arrangement of the filling regions 30 and the active regions 2, 4 and 6. A straight line shape as shown in FIG. 2 may minimize or reduce the area of the unit cell.

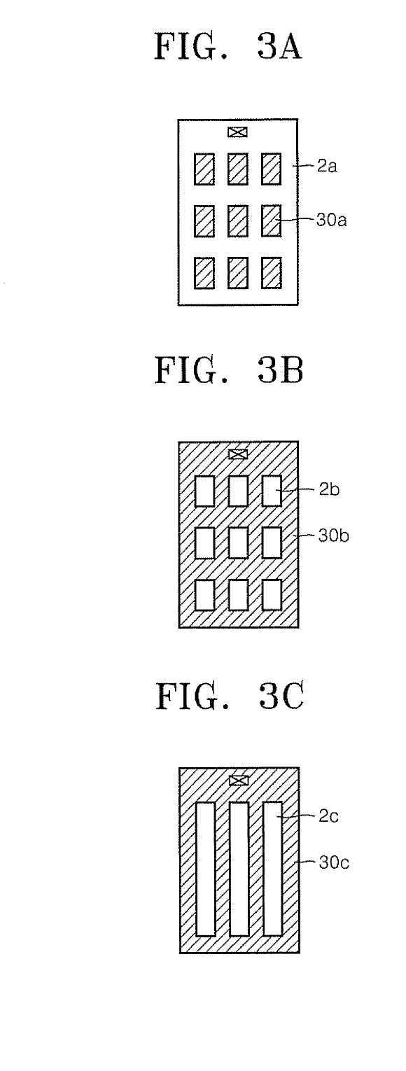

FIGS. 3A through 3C show examples of alternative layouts for an active region such as the first active region 2 in FIG. 2, according to various embodiments of the present invention. Referring to FIG. 3A, a plurality of first quadrangular filling regions 30a and a first active region 2a corresponding to a predetermined region minus the first quadrangular filling regions 30a are arranged on a semiconductor substrate. Referring to FIG. 3B, a plurality of first quadrangular active regions 2b and a filling region 30b corresponding to a predetermined region minus the first quadrangular active regions 2b are arranged on a semiconductor substrate, thereby forming a waffle shape. Referring to FIG. 3C, the arrangement of a plurality of first active regions 2c and a filling region 30c is the opposite to the layout shown in FIG. 2. That is, a plurality of first linear active regions 2c and a filling region 30 corresponding to a predetermined region minus the first linear active regions 2c are arranged on a semiconductor substrate. The number and shape of the first active region 2 and the filling regions 30 may vary depending on the programming speed and electrical characteristics of the EEPROM.

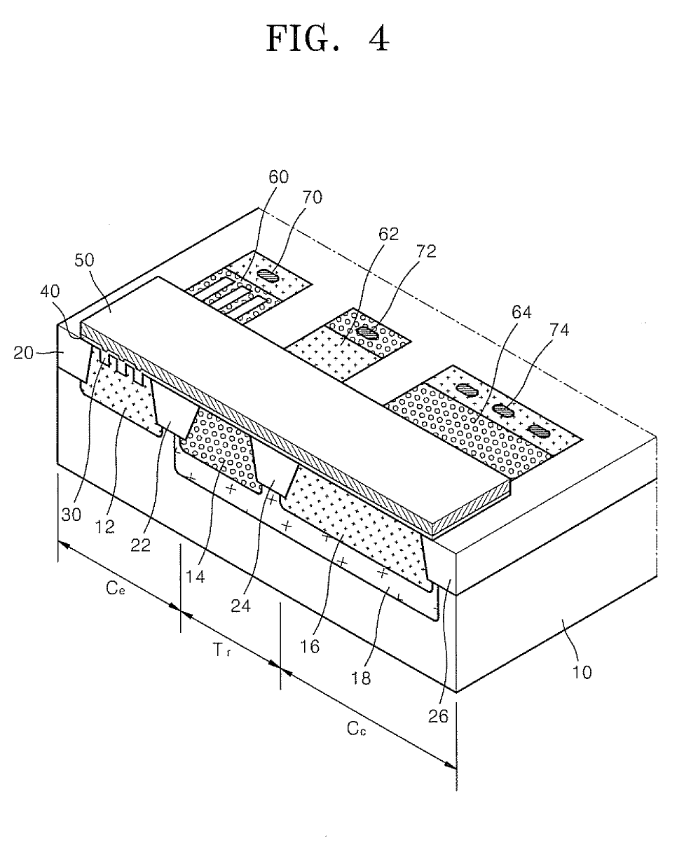

FIG. 4 is a perspective view of a section taken along a line IV-IV′ of FIG. 2. An EEPROM according to some embodiments of the present invention and a fabrication method thereof will now be described with reference to FIG. 4. Referring to FIG. 4, a first active region is defined on a semiconductor substrate 10 by a first device isolation layer 20 and a second device isolation layer 22. A second active region is defined on the semiconductor substrate 10 by the second device isolation layer 22 and a third device isolation layer 24. A third active region is defined on the semiconductor substrate 10 by the third device isolation layer 24 and a fourth device isolation layer 26. The semiconductor substrate 10 may be a P-type semiconductor substrate into which group V impurities are implanted. The device isolation layers 20, 22, 24 and 26 may, for example, be field oxide layers or shallow trench isolation (STI) layers.

Impurities of a first conductivity type are implanted into the semiconductor substrate 10 of the first active region to form an erase well 12. For example, impurities of a first conductivity type, such as arsenic (As) and phosphor (P), may be implanted into the semiconductor substrate 10 of the first active region to form an N-type erase well 12.

Impurities of a second conductivity type opposite to the first conductivity type are implanted into the semiconductor substrate 10 of the second active region to form a read well 14. For example, impurities of the second conductivity type, such as group III elements (e.g. boron (B)), may be used to form a P-type read well 14. Impurities of the first conductivity type are implanted into the semiconductor substrate 10 of the third active region to form a control well 16, for example, an N-type control well 16.

In addition, impurities of the first conductivity type are implanted into the semiconductor substrate 10 to surround the read well 14, thereby forming a deep well 18 of a different conductivity type than the read well 14. The read well 14 and the deep well 18 may reduce or prevent an impurity region of the second active region from being affected by a back bias that may be applied to the semiconductor substrate 10. The deep well 18 may surround the control well 16. The read well 14 and the deep well 18 may be omitted for convenience of fabrication.

A suitable ion implantation mask may be formed and used for the above well formation processes. When the same impurity or an impurity of the same concentration is implanted, the above well formation processes may be performed using one ion implantation mask, for convenience of fabrication.

An etch mask for trench formation is formed on the semiconductor substrate 10 of the erase well 12. The etch mask may have a good etch selectivity with respect to the semiconductor substrate 10, and may be formed using, for example, a nitride layer. Using the etch mask, the semiconductor substrate 10 of the erase well 12 is etched to form one or more trenches. The trenches are filled with an insulating material to form one or more first filling regions 30. The first filling region(s) 30 formed of an insulating material performs a device isolation function within the erase well 12. The first filling region(s) 30 may be formed in various shapes, such as linear shapes or quadrangular shapes. The insulating material filling the first filling region(s) 30 may be an oxide material. In order to cure damage to the semiconductor substrate 10 caused by the etching process, a thermal oxide layer may be further formed on the inner walls of the trenches, and an oxide material may be deposited into the trenches to form the one or more first filling regions 30.

Similarly, at least one second filling region (not illustrated) may be formed on the semiconductor substrate 10 of the read well 14. This is because F-N tunneling of electrons may occur also in the read well 14. Because the read well 14 is a region in which a read transistor will be formed, the second filling region may be formed in the read well 14 in order to reduce or prevent degradation of the read transistor by leakage current.

The etch mask is removed after the first filling regions are formed. The etch mask may be removed by dry polishing, wet polishing, or chemical-mechanical polishing (CMP). The etch mask may be removed by wet etching using an etchant. The etchant may have a good etch selectivity with respect to the insulating material filling the first filling region 30. Moats may be generated in an edge region of the first filling region 30 when the etch mask is removed. In addition, moats may be generated at an edge region of the first filling region 30 during a cleaning process. This is because the semiconductor substrate 10 may be damaged by the etching process for forming the trenches.

A floating gate insulation layer 40 is formed on the resulting structure in which the moats have been generated. The floating gate insulation layer 40 may be formed to a thickness of about 100-300 Å. The floating gate insulation layer 40 may be formed thinner over the moats than in other regions. Accordingly, during the operation of the EEPROM, an electric field may be concentrated on the thinner region of the floating gate insulation layer 40 to promote F-N tunneling of electrons. This may increase the programming speed of the EEPROM. The floating gate insulation layer 40 may be formed of an oxide material. If the first filling region 30 is formed of an oxide material, it may have an obscure boundary. The floating gate insulation layer 40 may be formed on and across the first filling regions 30, the erase well 12, the read well 14, and the control well 16.

A floating gate conduction layer 50 is formed on the floating gate insulation layer 40. The floating gate conduction layer 50 may be formed of polysilicon doped with impurities, for example, N-type impurities. The area of overlap between the floating gate conduction layer 50 and the control well 16 may be wider than that between the floating gate conduction layer 50 and the erase well 12 or the read well 14. This may be done to increase capacitive coupling in a control MOS transistor.

Impurities are implanted into the erase well 12 at respective sides of the floating gate conduction layer 50, thereby forming impurity-implanted regions. Specifically, impurities of the first conductivity type are implanted into the semiconductor substrate 10 at respective sides of the floating gate conduction layer 50, thereby forming impurity-implanted regions 60 in the erase well 12. The impurity-implanted regions 60 may increase capacitive coupling in the erase well 12, and may be omitted. Also, impurities of the first conductive type are implanted into the erase well 12 at a high concentration, thereby forming an erase well contact region 70. Consequently, the erase well contact region 70 has a higher impurity concentration than the erase well 12.

Impurities of the first conductivity type are implanted into the read well 14 at respective sides of the floating gate conduction layer 50, thereby forming impurity-implanted regions 62. The impurity-implanted regions 62 respectively form a source region and a drain region, and may be connected to different lines. Also, impurities of the second conductivity type opposite to the first conductivity type are implanted into the semiconductor substrate 10 of the first active region at a high concentration, thereby forming a read well contact region 72.

Impurities of the second conductivity type are implanted into the control well 16, thereby forming an impurity-implanted region 64. The impurity-implanted regions 64 may increase capacitive coupling in the control well 16, and may be omitted. Also, impurities of the first conductivity type are implanted into the control well 16 at a higher concentration than the first conductivity type impurities in the control well 16, thereby forming a read well contact region 72.

First, second, third and fourth lines (not illustrated) may be further formed after an interlayer insulating layer is formed on the semiconductor substrate 10 on which the floating gate conduction layer 50 has been formed. The first line is used to apply a common voltage to the erase well contact region 70 and the impurity-implanted regions 60 of the erase well 12. The second line is used to apply a common voltage to the read well 14 and one of the impurity-implanted regions 62 of the read well 14, while the third line is used to apply a voltage to the other one of the impurity-implanted regions 62. The fourth line is used to apply a common voltage to the control well contact region 74 and the impurity-implanted region 64 of the control well 16. The first, second, third and fourth lines respectively correspond to the erase, source, bit and word lines E/L, S/L, B/L and W/L in the EEPROM circuit diagram of FIG. 1.

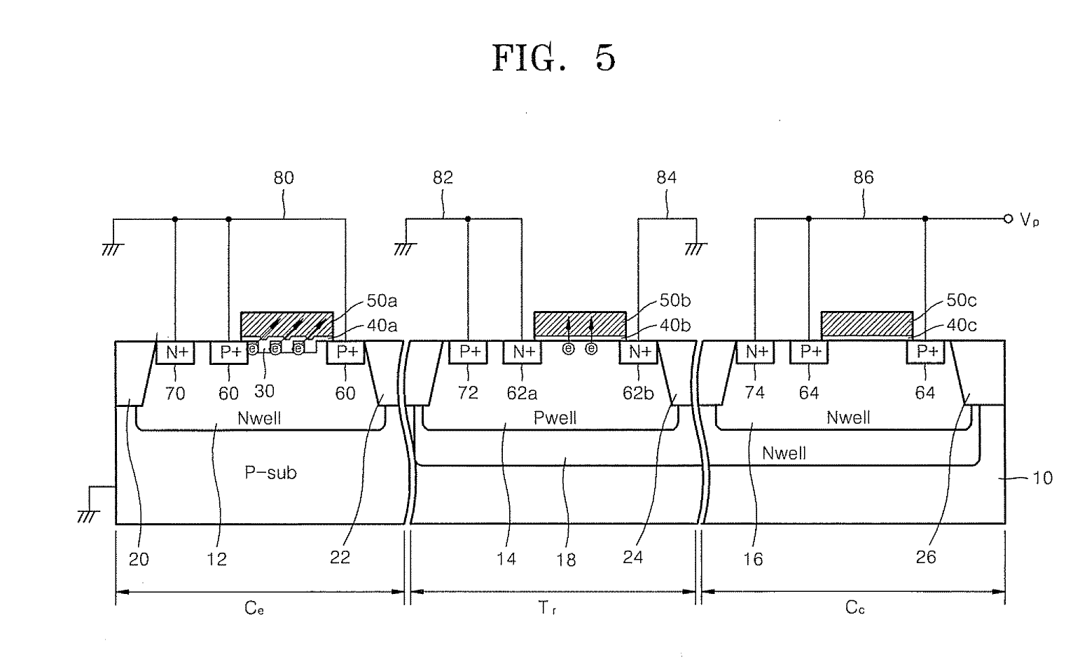

FIGS. 5 through 7 are sectional views illustrating operations of an EEPROM according to some embodiments of the present invention. The EEPROM operations will be described using a sectional view of the EEPROM including the active region with the quadrangular filling regions of FIG. 3A, with first, second, third and fourth lines 80, 82, 84 and 86 connected thereto.

FIG. 5 is a sectional view illustrating operations for programming data into the EEPROM according to some embodiments of the present invention. Referring to FIG. 5, the semiconductor substrate 10 is grounded and a ground voltage is applied through a first line 80 to the erase well 12 and the impurity-implanted regions 60. Thereafter, a program voltage Vp is applied through the fourth line 86 to the control well 16 and the impurity-implanted regions 64. When the deep well 18 is formed to surround the control well 16, the program voltage Vp is also applied to the deep well 18. The ground voltage can also be applied to the read well 14 and a source region 62a of a read transistor through the second line 82, and to a drain region 62b of the read transistor through the third line 84.

Accordingly, the program voltage Vp applied to the deep well 18, the impurity-implanted regions 64 and the control well 16 of a control MOS transistor Cc is capacitively coupled to a third region 50c of a floating gate. Thereafter, a strong electric field is created between the erase well 12 and a first region 50a of the floating gate. The floating gate insulation layer 40 formed on the semiconductor substrate 10 is thinner over the erase well 12 contacting the filling region 30, and thus the electric field is concentrated in the thinner area. Accordingly, electrons can be more easily stored in the floating gate by F-N tunneling through the floating gate insulation layer 40 formed on the semiconductor substrate 10 of the erase well 12 contacting the filling region 30. This may increase the programming speed of the EEPROM. Also, when the ground voltage is applied to the read well 14, a relatively strong electric field may also be created between the read well 14 and a second region 50b of the floating gate, and thus electrons can be stored in the floating gate by F-N tunneling. The program voltage Vp is selected to enable electrons of the erase well 12 to be F-N tunneled into the first region 50a of the floating gate. The program voltage Vp may be dependent on the thickness and permittivity of the floating gate insulation layer 40. For example, when the floating gate insulation layer 40 is an oxide layer with a thickness of about 150 Å, the program voltage Vp may be about 15 V. In some embodiments, the second line 82 and the third line 84 may be floated. In this case, the source region 62a, the drain region 62b and the read well 14 are floated, and thus data is programmed by F-N tunneling in the first region 50a and the erase well 12. This may protect the read transistor Tr.

The program voltage Vp is applied commonly to the control well 16 and the impurity-implanted regions 64, which may thereby reduce or prevent junction breakdown between the control well 16 and the impurity-implanted regions 64. The ground voltage is applied commonly to the erase well 12 and the impurity-implanted regions 60, which may thereby reduce or prevent junction breakdown between the erase well 12 and the impurity-implanted regions 60. Also, the ground voltage is applied commonly to the read well 14 and the source/drain regions 62a and 62b, which may thereby reduce or prevent junction breakdown between the read well 14 and the source/drain regions 62a and 62b. Although a reverse bias can be applied between the deep well 18 and the read well 14 and between the deep well 18 and the semiconductor substrate 10, because the read well 14 and the deep well 18 have a lower impurity concentration than the impurity-implanted regions 60, 62 and 64, the junction breakdown voltage between the deep well 18 and the read well 14 and between the deep well 18 and the semiconductor substrate 10 can be higher than the program voltage Vp. Accordingly, junction breakdown may be reduced or prevented during the data programming operation.

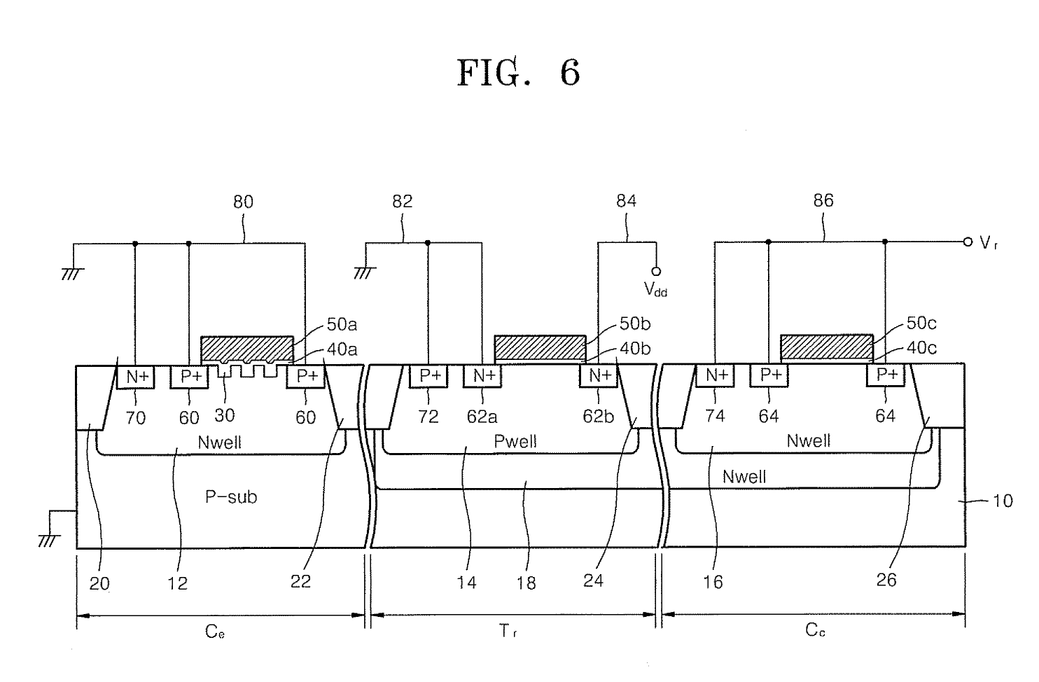

FIG. 6 is a sectional view illustrating operations for reading data from the EEPROM according to some embodiments of the present invention. Referring to FIG. 6, the semiconductor substrate 10 is grounded and a ground voltage is applied to the source region 62a of a read transistor. Thereafter, a source voltage Vdd is applied through the third line 84 to the drain region 62b of the read transistor. A read voltage Vr is applied through the fourth line 86 to the control well 16 and the impurity-implanted regions 64. When the deep well 18 is formed to surround the control well 16, the read voltage Vr is also applied to the deep well 18. The read voltage Vr may be about 5 V, and the source voltage Vdd may be about 3 V. Also, the ground voltage may be applied through the first line 80 to the erase well 12 and the impurity-implanted regions 60.

The read voltage Vr applied to the control well 16 is capacitively coupled to the third region 50c of the floating gate. When no electrons are stored in the floating gate, the voltage capacitively coupled to the third region 50c forms a channel in the read well 14 under the second region 50b of the floating gate. Accordingly, the read transistor Tr is turned on. On the other hand, when electrons are stored in the floating gate, the threshold voltage of the read transistor Tr is increased. Accordingly, when the read voltage Vr is applied, no channel is formed in the read well 14 under the second region 50b and thus the read transistor Tr is turned off. The third line 84 is used to sense the on or off state of the read transistor Tr.

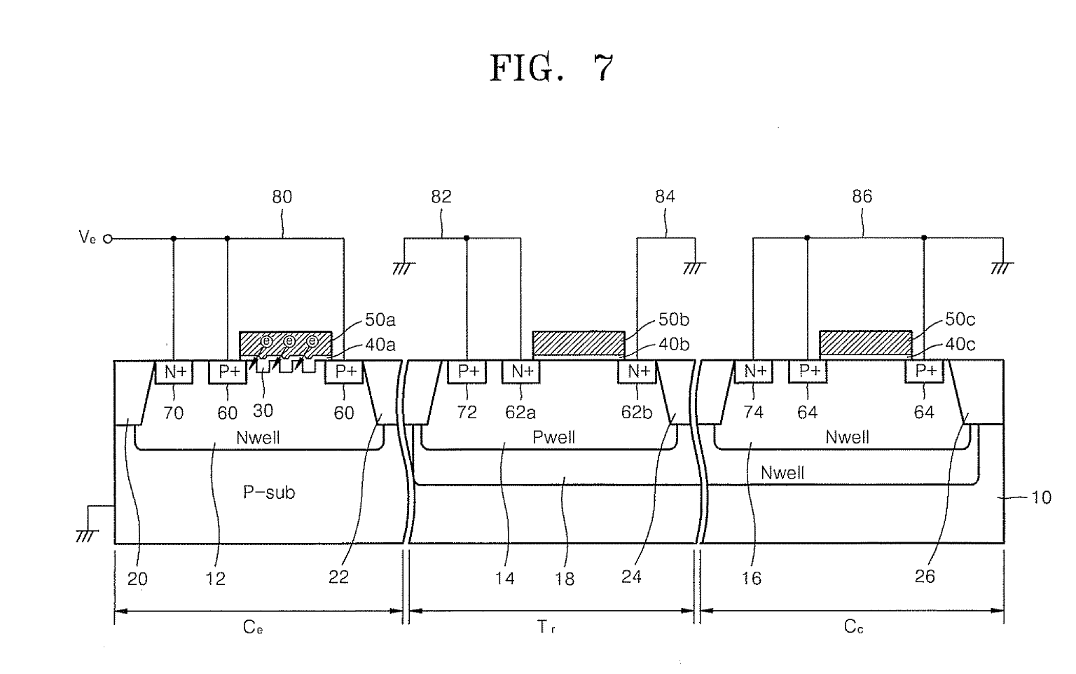

FIG. 7 is a sectional view illustrating operations for erasing data from the EEPROM according to some embodiments of the present invention. Referring to FIG. 7, an erase voltage Ve is applied through the first line 80 to the erase well 12 and the impurity-implanted regions 60. The semiconductor substrate 10 is grounded and the ground voltage is applied to the control well 16 and the impurity-implanted regions 64. The ground voltage can also be applied to the read well 14 and the source region 62a through the second line 82, and to the drain region 62b through a third line 84. The voltages may be applied respectively to the wells through the well contact regions 70, 72 and 74. When the deep well 18 is formed to surround the control well 16, the ground voltage is also applied to the deep well 18.

Accordingly, the ground voltage applied to the control well 16 is capacitively coupled to the third region 50c. Consequently, a strong electric field may be created between the first region 50a and the erase well 12. As in the data programming operations, the floating gate insulation layer 40 formed on the semiconductor substrate 10 may be thinner over the erase well 12 contacting the filling region 30, and thus the electric field may be concentrated in the thinner area. Accordingly, electrons may more easily F-N tunnel through the floating gate insulation layer 40, which may provide a relatively high data erasing speed for the EEPROM. The erase voltage Ve may be selected to enable electrons to be F-N tunneled. The erase voltage Ve may be, for example, about 15 V.

The ground voltage is applied commonly to the control well 16 and the impurity-implanted regions 64, which may thereby reduce or prevent junction breakdown between the control well 16 and the impurity-implanted regions 64. The erase voltage Ve is applied commonly to the erase well 12 and the impurity-implanted regions 60, which may thereby reduce or prevent junction breakdown between the erase well 12 and the impurity-implanted regions 60. Also, the ground voltage is applied commonly to the read well 14 and the source/drain regions 62a and 62b, which may thereby reduce or prevent junction breakdown between the read well 14 and the source/drain regions 62a and 62b. Although a reverse bias can be applied between the erase well 12 and the semiconductor substrate 10, because the erase well 12 has a lower impurity concentration than the impurity-implanted regions 60, the junction breakdown voltage between the erase well 12 and the semiconductor substrate 10 may be higher than the erase voltage Ve. Accordingly, junction breakdown may be reduced or prevented during the data erasing operations.

In addition, because the data erasing operation is performed by the F-N tunneling of electrons between the first region 50a and the erase well 12, no F-N tunneling of electrons is needed through the floating gate insulation layer 40 of the read transistor Tr. This may protect the read transistor Tr.

An EEPROM according to some embodiments of the present invention includes an active region with trenches, insulation regions filling the trenches, and a floating gate formed on the filling regions. Moats may be generated at edge regions of the filling regions due to damage by the etching process for forming the trenches. Accordingly, a floating gate insulation layer formed on the semiconductor substrate may be thinner where it contacts the filling regions than in other regions. During data programming and erasing operations, an electric field may be concentrated on the thinner regions of the floating gate insulation layer, which may aid F-N tunneling. Therefore, programming speed of the EEPROM may be increased.

The programming speed of the single-gate type EEPROM can be increased by facilitating capacitive coupling without increasing the area of the control MOS transistor. That is, the programming speed can be increased by allowing the F-N tunneling to more easily occur through the thin floating gate insulation layer formed on the semiconductor substrate contacting the filling regions, without increasing the size of the semiconductor device. Accordingly, an EEPROM according to some embodiments of the-present invention may enables fabrication of a miniaturized semiconductor device with good electrical characteristics.

The active region is etched using the etch mask, thereby forming the trenches. The trenches are filled with an insulation material to form the filling regions. Thereafter, the etch mask is removed to allow the moats to form in the edge regions of the filling regions. Thereafter, the floating gate insulation layer is formed on the entire surface having the moats, thereby thinning the floating gate insulation layer where it contacts the filling regions. Therefore, it may be easier to fabricate a high-speed single-gate type EEPROM suitable for a miniaturized semiconductor device.

In addition, it is possible to efficiently operate the high speed EEPROM with the single gate structure, without increasing the size of a semiconductor device. Because electrons may be more easily F-N tunneled through the thin floating gate insulation layer, the EEPROM may operate at a relatively high speed. Also, because data programming, erasing and reading operations may be performed in the separate regions, degradation of the read transistor may be reduced or prevented. Also, because a common voltage is applied to the erase well and its impurity-implanted regions, and the control well and its impurity-implanted regions, and because the deep well is formed to surround the control well, junction breakdown may be reduced or prevented and reliability may be improved.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. An integrated circuit device comprising:
a semiconductor substrate;
an isolation region defining an active region in the semiconductor substrate;
at least one filling region in at least one trench in the active region;
a floating gate insulation layer on the at least one filling region and the active region; and
a floating gate conductive layer on the floating gate insulation layer.

2. The device of claim 1, wherein the floating gate insulation layer includes a least one thinned portion proximate the at least one filling region.

3. The device of claim 1, wherein the at least one trench has a linear shape and/or a quadrangular shape.

4. The device of claim 1, wherein the active region has a linear shape and/or a quadrangular shape.

5. The device of claim 1, wherein the at least one trench comprises a plurality of trenches.

6. The device of claim 1, wherein the at least one filling region and the floating gate insulation layer each comprise an insulating material.

7. An electrically erasable programmable read-only memory (EEPROM) comprising:
a semiconductor substrate,
a device isolation region defining first, second and third active regions in the semiconductor substrate;
at least one first insulation region in at least one first trench in the first active region;
a floating gate insulation layer on the at least one first insulation region and the first, second and third active regions; and
a floating gate conduction layer on the floating gate insulation layer.

8. The EEPROM of claim 7, further comprising impurity-containing regions in each of the first, second and third active regions at respective sides of the floating gate conduction layer.

9. The EEPROM of claim 7, wherein the floating gate insulation layer includes at least one thinned portion proximate the at least one first insulation region.

10. The EEPROM of claim 7, wherein the first trench has a linear shape and or a quadrangular shape.

11. The EEPROM of claim 7, wherein the first active region has a linear shape and/or a quadrangular shape.

12. The EEPROM of claim 7, wherein the at least one first trench comprises a plurality of first trenches.

13. The EEPROM of claim 7, wherein the at least one first insulation region and the floating gate insulation layer each comprise an insulating material.

14. The EEPROM of claim 7, further comprising at least one second insulation region in at least one second trench formed in the second active region, and wherein the floating gate insulation layer is disposed on the at least one second insulation region.

15. The EEPROM of claim 14, wherein the floating gate insulation layer includes at least one thinned portion proximate the at least one second insulation region.

16. The EEPROM of claim 7, further comprising:
an erase well in the semiconductor substrate in the first active region and including impurities of a first conductivity type;
a read well in the semiconductor substrate in the second active region and including impurities of a second conductivity type opposite to the first conductivity type; and
a control well in the semiconductor substrate in the third active region and including impurities of the first conductivity type.

17. The EEPROM of claim 16, further comprising:
a first line connected to the erase well and the impurity-containing regions in the first active region;
a second line connected to the read well and one of the impurity implanted regions in the second active region;
a third line connected to the other one of the impurity implanted regions formed in the second active region; and
a fourth line connected to the control well and impurity implanted regions formed in the third active region.

18. The EEPROM of claim 16, further comprising a deep well including impurities of the first conductivity type and surrounding the read well.

19. The EEPROM of claim 7, wherein the floating gate has a linear shape.

20. A method of fabricating an EEPROM, the method comprising:
forming a plurality of device isolation layers defining first, second and third active regions in a semiconductor substrate;
forming at least one trench in the first active region;
forming at least one first insulation region in the at least one trench;
forming a floating gate insulation layer on the first, second and third active regions and on the at least one first insulation region; and
forming a floating gate conduction layer on the floating gate insulation layer.

21. The method of claim 20, wherein forming at least one trench region in the first active region comprises:
forming an etching mask on the semiconductor substrate including at least one opening exposing at least one portion of the first active region; and
etching the substrate using the etching mask to form the at least one trench.

22. The method of claim 20, wherein the floating gate insulation layer includes at least one thinned portion proximate the at least one first insulation region.

23. The method of claim 20, further comprising implanting impurities into the first, second and third active regions using the floating gate conduction layer as an ion implantation mask, thereby forming impurity-implanted regions.

24. The method of claim 23, further comprising:
implanting impurities of a first conductivity type in the first active region to form an erase well;
implanting impurities of a second conductivity type opposite to the first conductivity type in the second active region to form a read well; and
implanting impurities of the first conductivity type in the third active region to form a control well.

25. The method of claim 24, further comprising:
forming a first line connected to the erase well and the impurity implanted regions of the first active region;
forming a second line connected to the read well and one of the impurity implanted regions of the second active region;
forming a third line connected to the other one of the impurity implanted regions of the second active region; and
forming a fourth line connected to the control well and the impurity implanted regions of the third active region.

26. The method of claim 24, further comprising implanting impurities of the first conductivity type to form a deep well surrounding the read well.

27. A method of operating an EEPROM comprising first, second and third active regions defined on a semiconductor substrate by device isolation layers, at least one insulation region in at least one trench in the first active region, a floating gate insulation layer on the at least one insulation region and the first, second and third active regions, a floating gate conduction layer on the floating gate insulation layer, and impurity-containing regions in the first, second and third active regions at respective sides of the floating gate conduction layer, the method comprising:
programming data by respectively applying a ground voltage and a program voltage to the first active region and the third active region;
reading the programmed data by respectively applying a read voltage and a source voltage to the third active region and one of the impurity-containing regions of the second active region; and
erasing the programmed data by respectively applying the ground voltage and an erase voltage to the third active region and the first active region.

28. The method of claim 27, wherein electrons are F-N tunneled through the floating gate insulation layer formed on the semiconductor substrate of the first active region contacting the filling region, into the floating gate conduction layer, during the programming of data.

29. The method of claim 27, wherein electrons are F-N tunneled from the floating gate conduction layer, through the floating gate insulation layer formed on the semiconductor substrate of the first active region contacting the filling region, into the semiconductor substrate, during the erasing of the programmed data.

30. The method of claim 27, wherein the EEPROM further comprises an erase well in the first active region and including impurities of a first conductivity type, a read well in the second active region and including impurities of a second conductivity type opposite to the first conductivity type and a control well formed in the semiconductor substrate of the third active region and including impurities of the first conductivity type.

31. The method of claim 30, wherein the programming of data comprises:
applying the ground voltage to the erase well and the impurity-containing regions of the first active region;
applying the ground voltage to the read well and the impurity-containing regions of the second active region; and
applying the program voltage to the control well and the impurity-containing regions of the third active region.

32. The method of claim 30, wherein the reading of the programmed data comprises:
applying the ground voltage to the erase well and the impurity-containing regions of the first active region;
applying the ground voltage to the read well and one of the impurity-containing regions of the second active region;
applying the source voltage to another one of the impurity-containing regions of the second active region; and
applying the read voltage to the control well and the impurity-containing regions of the third active region.

33. The method of claim 30, wherein the erasing of the programmed data comprises:
applying the erase voltage to the erase well and the impurity-containing regions of the first active region;
applying the ground voltage to the read well and the impurity-containing regions of the second active region; and
applying the ground voltage to the control well and the impurity-containing regions of the third active region.
